(19) United States
(12) Patent Application Publication
(10) Pub. No.: US 2005/0275097 A1
(43) Pub. Date: Dec. 15, 2005

(54) Method of forming a solder bump and the structure thereof

(75) Inventor: Huang Min-Lung, Kaohsiung City (TW)

Correspondence Address: BIRCH STEWART KOLASCH & BIRCH, PO BOX 747, FALLS CHURCH, VA, 22040-0747, US

(73) Assignee: Advanced Semiconductor Engineering Inc.

(21) Appl. No.: 11/143,600

(22) Filed: Jun. 3, 2005

(30) Foreign Application Priority Data
Jun. 10, 2004 (TW) 93116706

(51) Int. Cl. H01L 29/40

(52) U.S. Cl. 257/737

(57) ABSTRACT

A method of forming a solder bump and the associated structure is disclosed. A chip having a conductive pad is covered with a mask layer and exposing a potion of said conductive pad of said chip. Conductive material is then formed above the conductive pad not covered with said mask layer. After applying a flux material on the formed conductive material, a solder structure having a lower melting point than the conductive material is placed, and subsequently is reflowed at a temperature lower than the melting point of the conductive material. After removing the mask layer, the solder bump with increased height and reliability is thus attained.

### BACKGROUND OF THE INVENTION

1. Field of the Invention

The present invention generally relates to the structure and the forming method of a solder bump, and more particularly to a solder bump with increased height and reliability.

2. Description of the Prior Art

Flip chip technology has become one of the mainstreams to improve cost, reliability and productivity in the electronic packaging industry, relative to wire bonding technology. FIG. 1A to FIG. 1D are sectional views illustrating the steps of forming the solder bump using a conventional flip chip technology. Referring to FIG. 1A, a chip 100 is provided with conductive pad 102 formed on its surface, and then a passivation layer 104 is formed on the chip 100 to protect the chip 100. Thereafter, the passivation layer 104 is partially removed to expose the surface of the conductive pad 102, followed by covering the conductive pad 102 and the passivation layer 104 with under bump metallization (UBM) 106, which provides adhesion and wettability.

Referring to FIG. 1B, a photoresist layer 108 is formed on the under bump metallization 106, and is then lithographically patterned to form a hole 110 therein, which exposes a portion of the under bump metallization 106.

Subsequently, conductive material, such as solder material 120, is electroplated to fill the hole 110, as shown in FIG. 1C.—Thereafter, referring to FIG. 1D, the photoresist layer 108 is removed, and the solder bump 120 is under reflow.

According to the description discussed above, the conventional solder bump 120 has limited height, so that the gap height between the chip 100 and a package substrate (not shown in the figure) is not high enough to sustain a reliable interconnection. Although some methods are proposed to overcome this problem, these methods largely are not practical due to their inherent complexity. Accordingly, an improved structure and forming method of a solder bump is thus required, so that the solder bump with increased height and reliability can be uncomplicatedly manufactured.

### SUMMARY OF THE INVENTION

In view of the foregoing, it is an object of present invention to provide a solder bump with increased height to be used in the integrated circuit bonding interconnection, such as the flip chip interconnection, and accordingly improve the reliability of the interconnection.

It is another object of the present invention to furnish a simplified, and thus low cost, method of forming a solder bump to be used in the integrated circuit bonding interconnection, such as the flip chip interconnection.

In accordance with one embodiment of the present invention, a method of forming a solder bump is disclosed. A chip having a conductive pad is covered with a mask layer having a hole at a location above the conductive pad. Conductive material is then filled into the hole. After applying flux material on the formed conductive material, a solder structure having a lower melting point than the conductive material is placed, and subsequently is reflowed at a temperature lower than the melting point of the conductive material. The solder bump made of the filled conductive material and the solder structure with increased height and reliability is thus attained after removing the mask layer.

In accordance with one embodiment of the present invention, the structure of a solder bump is disclosed, which comprises a chip having a conductive pad, and under bump metallization formed at least on the conductive pad. A conductive post is further positioned on the under bump metallization at a location above the conductive pad, and a solder structure is coupled to the conductive post, wherein the conductive post and the solder structure together constitute the solder bump.

### BRIEF DESCRIPTION OF THE DRAWINGS

FIG. 1A to FIG. 1D are sectional views illustrating the steps of forming a solder bump using a conventional technique; and

FIG. 2A to FIG. 2E are sectional views illustrating the steps of forming a solder bump according to one embodiment of the present invention.

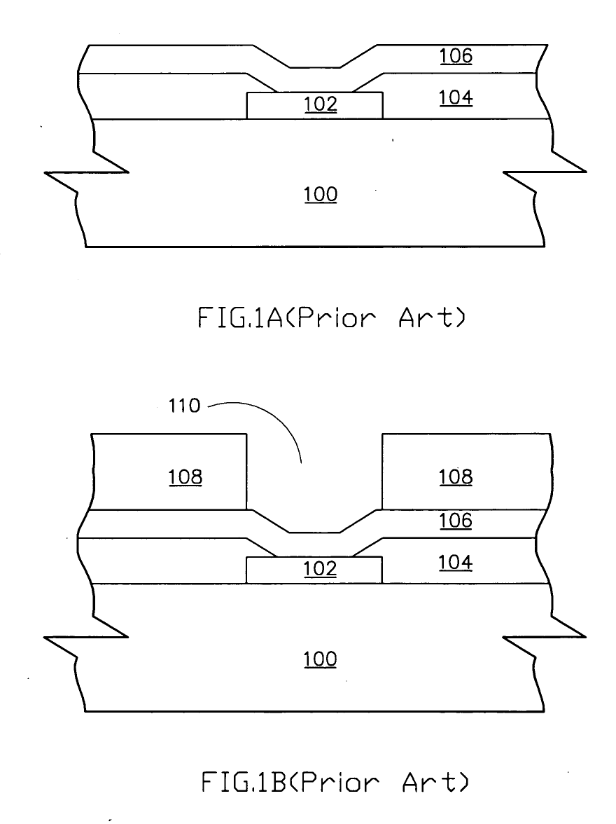

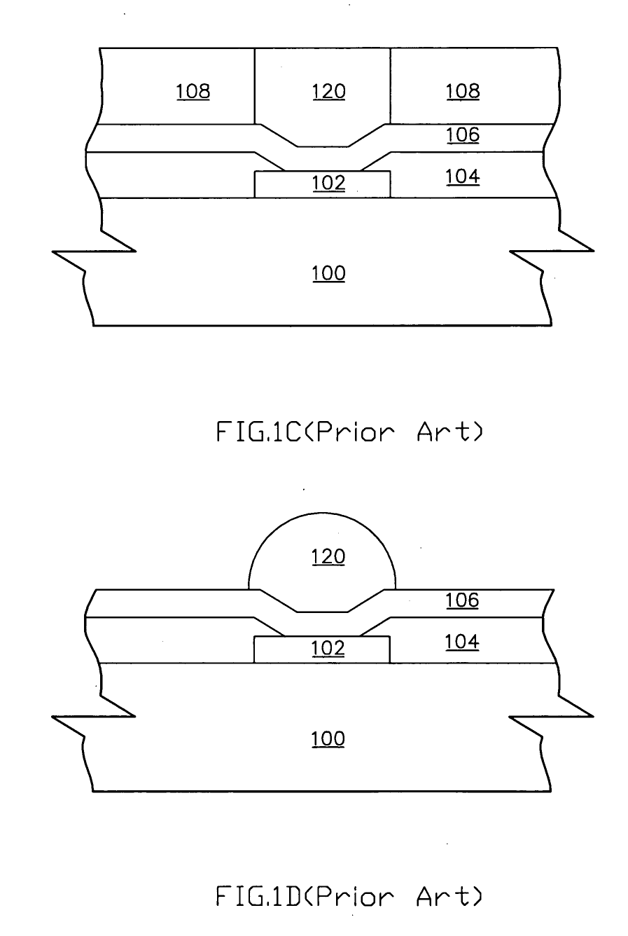

### DESCRIPTION OF THE PREFERRED EMBODIMENT

Some sample embodiments of the invention will now be described in detail. Nevertheless, it should be recognized that the present invention can be practiced in a wide range of other embodiments besides those explicitly described, and the scope of the present invention is expressly not limited except as specified in the accompanying claims.

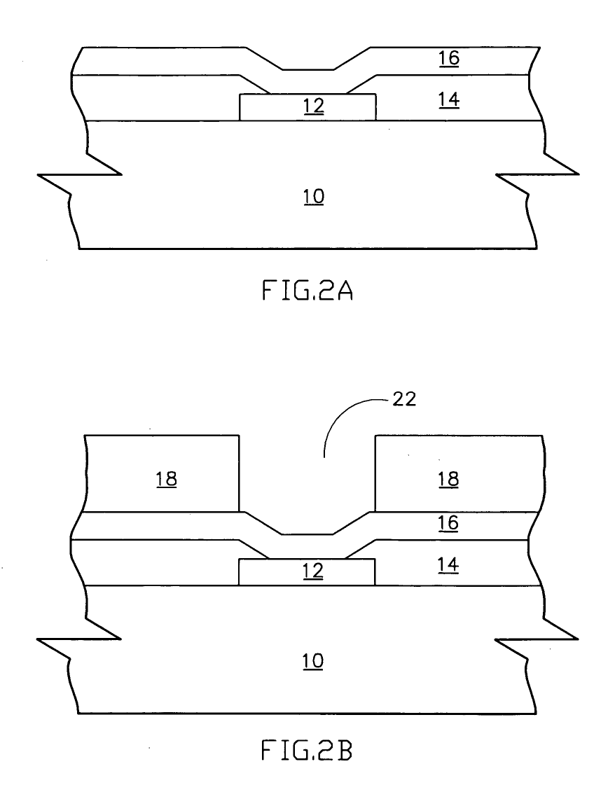

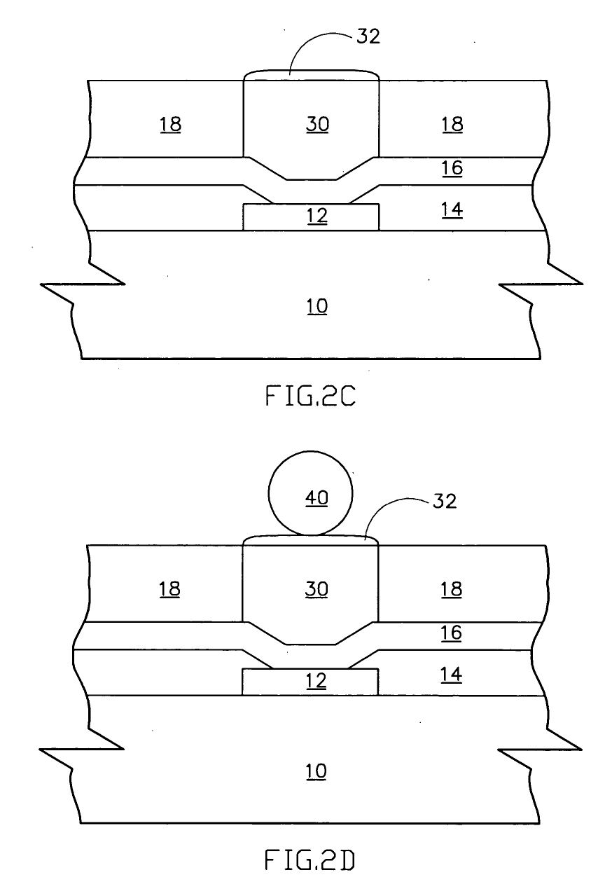

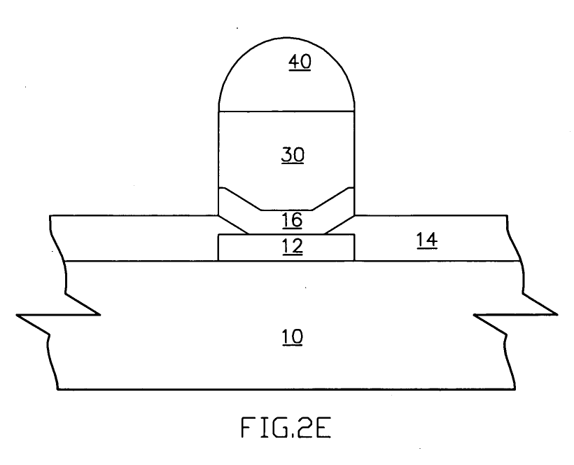

The present invention provides a method for increasing the height of a solder bump, and therefore improving the reliability of the solder bump. FIG. 2A to FIG. 2E are sectional views illustrating the steps of forming the solder bump according to one embodiment of the present invention. As shown in FIG. 2A, a semiconductor device 10 is provided with a conductive pad 12 formed on its surface. In the embodiment of the present invention, the semiconductor device 10 is a wafer, and the conductive pad 12 could be made of conductive material, such as aluminum or copper. A passivation layer 14 is formed on the semiconductor device 10, and then the passivation layer 14 is partially removed to expose—a portion of the surface of the conductive pad 12. Thereafter, the under bump metallization 16 is formed over the passivation layer 14 and the exposed conductive pad 12, for example, by using conventional sputtering, deposition, or electroplating techniques. In this embodiment, the under bump metallization 16 serves as an interface between the conductive pad 12 and a solder bump to be formed in the subsequent steps. Specifically, the under bump metallization 16 acts as a buffer layer for stress relief, provides good adhesion, and provides protection from corrosion. The under bump metallization 16, which is made of, for example, Al/Cu, Cr/Cu, or Al/Ni-V(vanadium)/Cu composite metal layer, also serves as a wetting layer for the subsequent solder bump to wet and react.

Referring to FIG. 2B, a photo-sensitive mask layer 18, such as a dry film photoresist layer, is formed on the under bump metallization 16. Subsequently, this mask layer 18 is lithographically patterned to form a hole 22 therein at the predetermined solder bump location. In this embodiment, the hole 22 is located above the previously exposed conductive pad 12.

As shown in FIG. 2C, the conductive material 30 is filled in the hole 22 by electroplating or printing so that the height of the conductive material 30 is same as the mask layer 18. It is noted that the filled conductive material 30 serves as a post, constituting a part of the solder bump to be formed. This conductive post 30 could be cylindrical in shape. The conductive post 30 could be made of solder, such as 95 wt. % lead/5 wt. % tin, having high melting point; or other metal having high melting point, such as copper (with melting point 1083° C.), gold (with melting point 1063° C.), or nickel (with melting point 1455° C.). Due to the high melting point, the conductive post 30 does not fuse during reflow or soldering process. The flux material or pre-solder material 32 is further applied for example through printing, on the surface of the conductive post 30 to relieve the surface tension of the metal interface, and to provide good anti-corrosion, foaming, volatility, and adhesion during soldering.

As shown in FIG. 2D, a solder ball 40 is positioned on the flux material 32 to couple with the conductive post 30 by using conventional ball placement technique, constituting another part of the solder bump. The solder ball 40 can be made of solder, such as 37 wt. % lead/63 wt. % tin, or other conductive material having a melting point (about 183° C.) lower than that of the conductive post 30.

Referring to FIG. 2E, a reflow process is performed at temperature equal to or higher than the melting point of the solder ball 40 but lower than the melting point of the conductive post 30, therefore resulting in the solder bump with lower melting point and the conductive post with high melting point. Owing to its higher melting point, the conductive post 30 does not fuse during soldering, and therefore the gap height between the chip and a package substrate (not shown in the figure) can be kept. Finally, portions of the mask layer 18 and the under bump metallization 16 not covered by the conductive post 30 are removed.

Although specific embodiments have been illustrated and described, it will be obvious to those skilled in the art that various modifications may be made without departing from what is intended to be limited solely by the appended claims.

1. A method of forming a solder bump, comprising:
providing a semiconductor device having a conductive surface thereon;
forming a mask layer covering said semiconductor device, and exposing a potion of said conductive surface of said semiconductor device;
forming a conductive material above the conductive surface;
applying a flux material on said—conductive material;
positioning a solder structure on said flux material to contact said flux material, wherein the melting point of said solder structure is lower than the melting point of said conductive material;
reflowing said solder structure, wherein said reflowing is performed at a temperature lower than said melting point of said conductive material; and
removing said mask layer.

2. The method according to claim 1, after said semiconductor device is provided, further comprising:
forming a conductive pad on said semiconductor device;
forming a passivation layer on said semiconductor device, and exposing a portion of said conductive pad; and
forming an under bump metallization contacted said exposed conductive pad and said passivation layer.

3. The method according to claim 2, wherein said step of forming said under bump metallization comprises sputtering a plurality of metal layers.

4. The method according to claim 2, further comprising removing said under bump metallization not covered by said formed conductive material after said mask layer is removed.

5. The method according to claim 1, wherein the step of forming said mask layer comprises:
forming a dry film photoresist layer over said semiconductor device;
lithographically patterning said dry film photoresist layer; and
removing a portion of said dry film photoresist layer to expose a portion of said conductive surface.

6. The method according to claim 1, wherein said step of forming said conductive material comprises electroplating solder material including lead and tin, said lead has higher weight percentage than said tin.

7. The method according to claim 1, wherein said step of forming said conductive material comprises electroplating a copper based material.

8. The method according to claim 1, wherein said solder structure comprises solder made of 37 wt. % lead/63 wt. % tin.

9. A method of forming a solder bump, comprising:
providing a chip;
forming a conductive pad on said chip;
forming a passivation layer on said chip, and exposing a portion of said conductive pad;
forming an under bump metallization on said exposed metal pad and said passivation layer;
forming a mask layer on said under bump metallization, wherein said mask layer has a hole therein exposing said under bump metallization;
filling a conductive material in said hole of said mask layer;
applying a flux material on said filled conductive material;
positioning a solder structure on said flux material;
reflowing said solder structure at a temperature lower than a melting point of said conductive material;
removing said mask layer; and
removing said under bump metallization not covered by said filled conductive material.

10. The method according to claim 9, wherein said step of forming said under bump metallization comprises sputtering a plurality of metal layers.

11. The method according to claim 9, wherein said step of forming said under bump metallization comprises electroplating a plurality of metal layers.

12. The method according to claim 9, wherein said step of filling said conductive material comprises electroplating a solder material including lead and tin, wherein said lead has higher weight percentage than said tin.

13. The method according to claim 9, wherein said step of filling said conductive material comprises electroplating a copper-based material.

14. The method according to claim 9, wherein said solder structure comprises solder made of 37 wt. % lead/63 wt. % tin.

15. The method according to claim 9, wherein said step of positioning the solder ball is performed by using ball placement technique.

16. A solder bump used in flip chip interconnection, comprising:
a semiconductor substrate having a conductive pad positioned thereon;
an under bump metallization formed at least on said conductive pad;
a conductive post positioned on said under bump metallization at a location above said conductive pad; and
a solder structure coupled to said conductive post.

17. The solder bump according to claim 16, wherein said conductive post is cylindrical in shape.

18. The solder bump according to claim 16, wherein said conductive post comprises a solder material including lead and tin, wherein said lead has higher weight percentage than said tin.

19. The solder bump according to claim 16, wherein said solder structure has a lower melting point than said conductive post.

20. The solder bump according to claim 16, wherein said solder structure comprises solder made of 37 wt. % lead/63 wt. % tin.
